(19) United States
(12) Patent Application Publication
(10) Pub. No.: US 2005/0157891 A1
(43) Pub. Date: Jul. 21, 2005

(54) Method of digital equalisation of a sound from loudspeakers in rooms and use of the method

(76) Inventor: Lars Gottfried Johansen, Storvorde (DK)

Correspondence Address: DYKEMA GOSSETT PLLC, FRANKLIN SQUARE, THIRD FLOOR WEST, 1300 I STREET, NW, WASHINGTON, DC, 20005, US

(21) Appl. No.: 10/516,368

(22) PCT Filed: Jun. 12, 2003
(86) PCT No.: PCT/DK03/00390

(30) Foreign Application Priority Data
Jun. 12, 2002 (DK) PA 2002 00888

(51) Int. Cl. H03G 5/00

(52) U.S. Cl. 381/103

(57) ABSTRACT

A method of digitally equalising the sound from a loudspeaker that is placed in a certain room, said room having varying acoustic properties affecting the way a user perceive the sound, is corrected in a certain part of the room, by measuring one or more impulse responses through a microphone, said impulse responses being processed in a pre-processing algorithm, in at least two parallel frequency band correction algorithms and a post processing algorithm. As an option a pre-correction algorithm can be coupled between the pre-processing algorithm and the frequency band correction filters. The pre-correction algorithm is adapted to receive input representing measured loudspeaker characteristics under ideal condition in an anarchic room, and/or parameters from a reflections attenuation algorithm. From the post processing algorithm the final filter parameters are stored and used for correcting sound from a source connected to the amplifier feeding the loudspeaker to the acoustic behaviour of the actual room the loudspeaker is placed in. If any parameters in the room are changed then the correction method according to the invention can be repeated in order to set up new filter parameters.

This invention relates to a method of digitally equalising sound from loudspeakers placed in a room having a combined loudspeaker/room transfer function, said method comprising placing a microphone in the room, emitting one or more pulses from a loudspeaker through an amplifier and measuring the impulse response in a desired listening position, said method.

Moreover the invention relates to a use of the method.

High Fidelity in Sound Reproduction.

Since the loudspeaker was devised over a hundred years ago, the aims in sound reproduction has gradually changed and become still more ambitious. In the very beginning of sound reproduction history the realistic technical goals were related to sound volume level, amplification, acoustical efficiency etc. Today these issues give us no real technical challenge anymore. The striving has moved forward and has in the last part of the 20th century been related to the quality in sound reproduction.

When the stereophonic recording technology was introduced in the early nine-teen fifties (and stereo radio-gramophones became accessible to much more people), the interest in reproduction quality with reference to real event took a big step forward. For the past approximately forty years high fidelity has grown to become an indispensable term in sound reproduction, at least when dealing with home audio systems. Today, the ultimate goal is to produce transparent reproduction systems, i.e. system which, due to their physical, electrical, or acoustic nature, do not add an audible properties to the original signal. From a technically point of view however, it is not a very well defined goal.

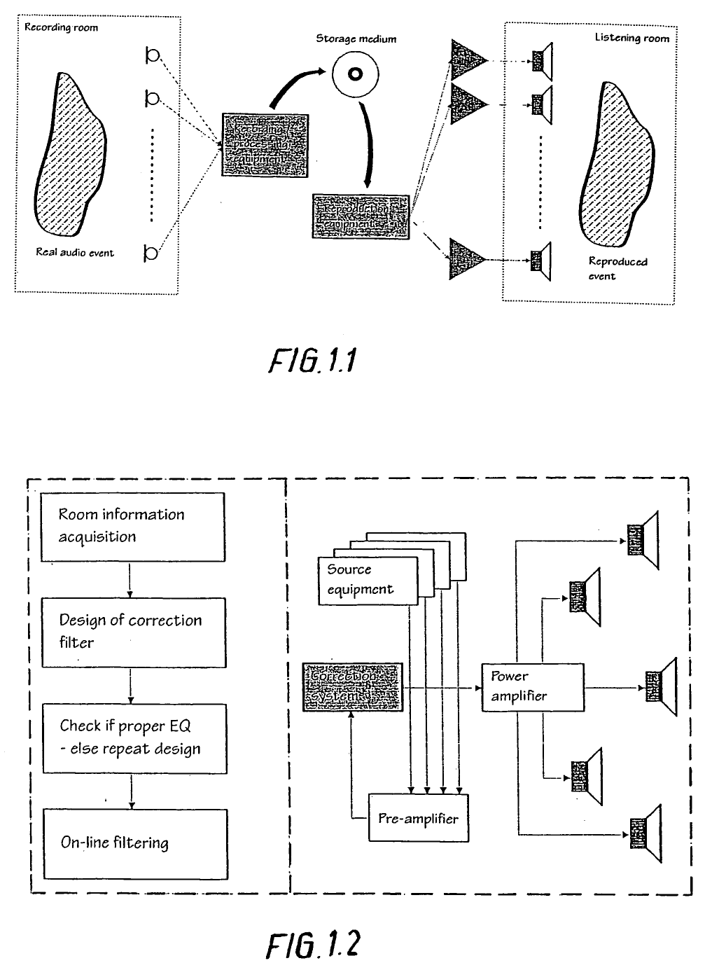

The term high fidelity encompasses the entire reproduction system and expresses to what extent reproduced sound matches the real event. Most elements in the sound reproduction chain will deteriorate sound and added together the reproduced event usually ends up far from being an exact copy of the real event, see FIG. 1.1. Below is listed where high fidelity is likely to suffer.
Recording technology and processing
Storage of recorded information/signals
Conversion of stored information to electrical signals
Conversion of signals (analog/digital)
Amplification technology
Electrical to acoustic signals transducers (loudspeakers/headphones)
Sound reproduction room

Traditional two channel recording technology has developed to capture real events in a consistent manner (there are ongoing discussions though concerning the recording setups and standards for the novel multi channel systems), and digital technology seems to have passed the initial problems. Similarly, amplifiers today can be constructed so that ultimate transparency is close. Yet it is thought-provoking that forty year old analog LP recordings played back using state-of-the-art tube amplifiers still offer a performance comparable to what is achieved by today's technology—at least from a subjective quality perspective.

The conclusion could be that the next big step towards transparent high fidelity sound reproduction is going to be taken in the acoustic field, i.e. how amplified electrical signals are converted into sound and how the sound pressure is affected by the surroundings before it reaches the listener's ears. So to further improve reproduced sound, focus should be put on loudspeakers and rooms.

Many prejudices exist concerning which system components affect the reproduced sound at most and which do not have a noticeable impact. Some of the attitudes and beliefs are confirmed by technical measurements and some are not. Some are generally agreed upon through subjective listening point of views (though perhaps not possible to confirm through system measurements) and some are highly individual. Yet, fundamentally speaking, when performing blind listening tests (subjects do not know which manipulations are made), it shows that most people are capable of evaluating various characteristics in a uniform way independently of personal preferences.

Relating to reproduction transparency, the only appropriate reference is a real event,—so what most people find attractive is a reproduced sound that creates the illusion and the feeling of participating in a real event, i.e. the sense of “being there”. Although it may be possible some day to substantiate through measurements and proper interpretations the characteristics that separate good illusions from not so good ones, the definitive evaluations must probably always be subjectively based.

The Listening Room Impact.

When sound is generated in the loudspeaker as an electrical to acoustic transduction, the last transmission path of the sound before it reaches the listener's ear goes through the listening room. Since the room forms an enclosure and sound is emanated from the loudspeaker in almost all directions, this last acoustic transmission path has a significant influence on the perceived sound. The room may be well optimised for sound reproduction but will always contribute to the event with its own acoustic properties. This may or may not be beneficial to the illusion of a real event—usually it is not.

It is tempting to imagine a sound reproduction event without room acoustic influence. Such is obtained in a free field for example,—that however not being compatible with average listening conditions! Otherwise an anechoic room can be employed,—a room designed in such a way that only the direct sound from the loudspeaker reaches the listener's ears (no reflections at all). That solution too is not feasible in average home listening rooms; the physical implications of such a room are far from being compatible with standard technologies in house building. On the bottom line the question is if that condition then really is desirable, even if it were realisable?

Instead, compensation for the more or less ideal acoustic properties is an approach. Some of the acoustic properties can be changed by applying passive damping material placed on walls, floor, or ceiling, or absorbers can be used. Another way of compensating for the acoustics is to use electrical equalisers, usually put in the reproduction system just before the power amplifier. Such equalisers can alter the frequency magnitude content of the reproduced sound but inherently they also alter frequency phase characteristics which relate to reproduction of transient signals. Generally speaking, they most often introduce a set of bad properties when they try to correct the room acoustics. So from a high fidelity point of view, traditional equalisers are not adequate (or even desirable) and we need to replace them with better technology.

Room Acoustics Correction by Digital Electronics.

Digital technology offers a potential of much more advanced equalisers, or in a broader sense—correction systems. By digital electronic technology employing signal processors (DSP), it becomes considerably easier to realise what may be the goal from an idealistic point of view. Essentially, formulating the problem, devising algorithms for appropriate solutions, and programming these in one (or more) DSP give much more degrees of freedom compared to traditional analog equalisers.

Such approaches though demand detailed information of the room acoustical properties. Unfortunately, in the same room some of the acoustic properties vary considerably depending on the physical position of the loudspeaker and the receiver (listener or measurement microphone). This phenomenon is referred to as the point-to-point sensitivity scenario. Hence, immediately it seems hopeless to design practical correction systems if they are bound to work properly in one physical point only. Fortunately, there are also common characteristics as is revealed later on.

So the peculiar situation is that the digital technology and the mathematics may offer the potential of very exact room acoustics correction (in a very limited space of the room,—a point in fact) but realistic physical considerations dictate that we can not make full use of this potential. It is a must that correction applies to a larger space, if not the entire room.

The Concept of a Practical Correction System.

The first basic demand to a room correction system is naturally that the subjectively perceived quality of sound reproduction somehow is improved, and the second one is that it must be simple in use. The high level specifications of a practical correction system could read;
stand-alone system, no need for external computers,
multi-channel capability,
reasonable hardware complexity, e.g. comparable to that of a good multi format decoder (MP3, DTS, Dolby ProLogic etc.),
off-line operating time preferably below 30 seconds,
objective and subjective improvement in a reasonable space around the listening position, e.g. 1 m², and no severe artefacts elsewhere in the room.

Operating the system should be as simple as possible. The user places a microphone in a preferred position, or perhaps in more positions relatively close to each other, and lets the system acquire room acoustics information. Subsequently, the system computes the proper correction algorithms for each channel, see FIG. 1.2 (left). Now, the algorithms are stored and signal input is fed to the correction system from the signal sources through the pre-amplifier as depicted on FIG. 1.2 (right). Finally, the corrected signals are fed to the power amplifiers and loudspeakers. This set up is referred to as a pre-filtering correction since the signal is actually electronically modified beforehand in order to accommodate to the later transformations due to the room acoustics.

Summary of Room Acoustics and Acquisition of Room Acoustic Information.

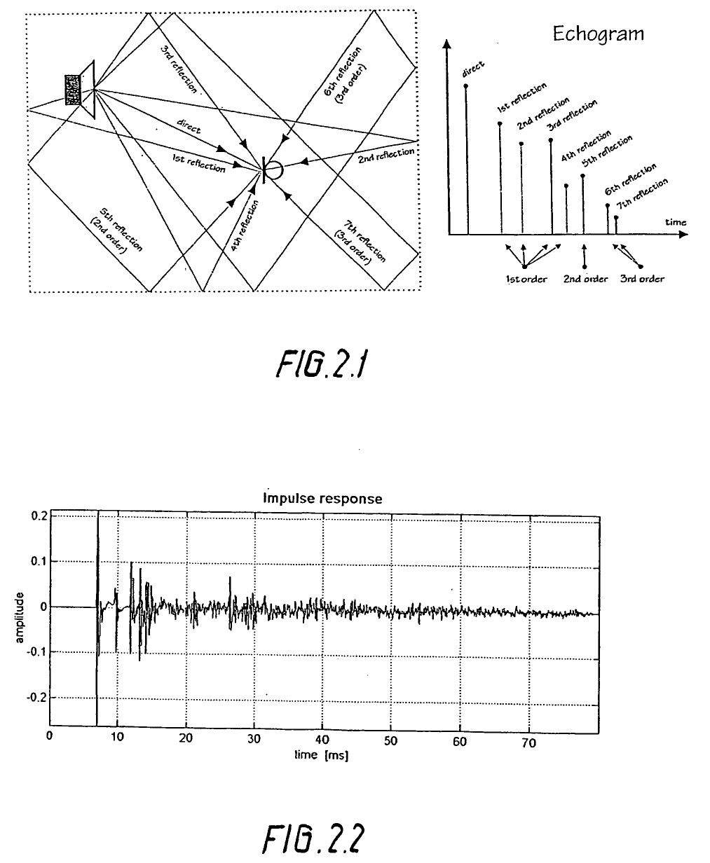

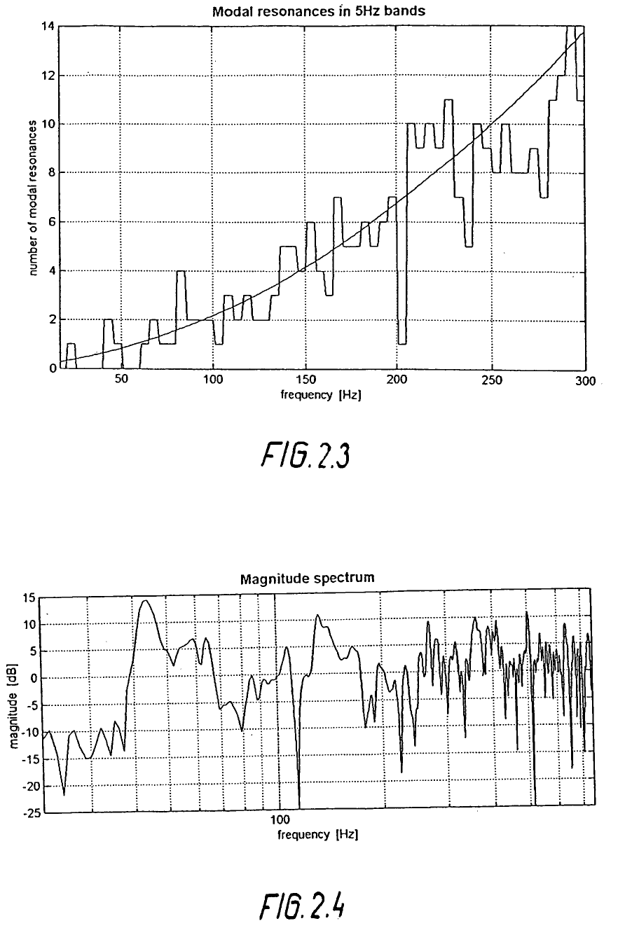

The received sound in a given spot coming from loudspeakers consists of more elements. First to arrive is the direct sound from the source, and afterwards a collection of multiple and altered versions of the sound appear. These sounds have been hit and reflected by one or more boundary surfaces or interior elements, see FIG. 2.1, and apart from them being delayed they are most likely also attenuated, since almost all materials absorb sound energy by some fraction α. In FIG. 2.1, the sounds are shown as beams emitted from a loudspeaker and received by a microphone. Since that consideration is valid only for wavelengths considerably smaller than any of the room dimensions, it is not custom to associate reflections with low frequency phenomena. Seven reflected beams are shown—the first four of first order (one reflection), one of second order (two reflections), and two of third order (three reflections). As time elapses, the number of reflections grows, hence eventually the received sound at the microphone can be considered as an infinite sum of sound beams travelling through different transmission paths.

Impulse Response Splitting Into Three Parts

In FIG. 2.2 is shown 100 ms of an arbitrary impulse response measurement from a listening room, and it becomes apparent that it can be considered consisting of three parts that deserve separate attention;
direct sound,
separable reflections,
non-separable reflections also denoted the reverberation tail.

At some time tstat it becomes hard to separate reflections since they are so many in a short time interval t The number of reflections Dₑ up to time t₀ is given in eq. 2.1. The time tₛₜₐₜ, called the statistical time (or mixing time), can be defined by eq. 2.2 where the ratio N/tdenotes the echo density, and beyond this limit it will be more appropriate to treat the impulse response in a statistical manner. Reverberation radius r_{reverb} is defined in eq. 2.3, and it says in what distance from the source the sound field becomes diffuse. Most of the sound energy perceived under normal listening conditions (with distance app. 3 m from the speakers in home listening rooms) comes from reflected beams since r_{reverb} typically is 0.5-1 m.

$$\begin{matrix}{D}_{e} ( {t}_{0} ) = 4 π {c}^{3} \frac{{t}_{0}^{2}}{V} & 2.1 \\ {t}_{stat} = \sqrt{\frac{V}{4 π {c}^{3}} \frac{Δ N}{Δ t}} \approx 2 \sqrt{V} for \frac{Δ N}{Δ t} = 2000 & 2.2 \\ {r}_{reverb} = \sqrt{\frac{{A}_{a bs , eq}}{16 π}} & 2.3\end{matrix}$$

Modal Resonance Frequencies.

Frequency domain analysis is often associated with the transfer function counter part of the impulse response. In section 2.2 the time domain is roughly split in a separable reflections part below tₛₜₐₜ and a statistical reverberation part beyond tₛₜₐₜ. A similar consideration can be made in the frequency domain. Due to the wave nature of sound, at low frequencies the room dimensions will for certain wavelengths equal a relatively small integer number of half wave-lengths. Thus between parallel surfaces, standing waves will be observed and for such frequencies a resonance occurs.

When one dimension of the room, say Iₓ, equals one half the wavelength, the standing wave is said to cause a first order mode (nₓ=1) room resonance (when Ix equals two half wavelengths we have a second order mode, nₓ=2). Standing waves also occur by reflection on more than two parallel surfaces, e.g. Sₓ and S_{z}, and the complete set of resonance frequencies (of which, by principle, the number is infinite) can be determined from eq. 2.4 which applies for a rectangularly shaped and fully reflecting room. By combining the modes nₓ, n_{y}, n_{z} (1,0,0; 0,1,0; 0,0,1; 1,1,0 and so on), in FIG. 2.3 (the bar line) is shown the summed number of modal resonances in successive bands of 5 Hz. The smooth curve is the predicted number of modal resonances as a function of the frequency.

$${f}_{N} = \frac{c}{2} \sqrt{{( \frac{{n}_{x}}{{l}_{x}} )}^{2} + {( \frac{{n}_{y}}{{l}_{y}} )}^{2} + {( \frac{{n}_{z}}{{l}_{z}} )}^{2}} \qquad 2.4$$

Clearly, the number of resonances in a frequency band increases with frequency, and at some point it is no longer possible to separate the resonances from each other. When that happens, a statistical approach to further analysis is more convenient. This is a situation much like the one depicted for the time domain reflections. In analogy to the time domain measure tₛₜₐₜ, Schroeder has proposed the measure given in eq. 2.5, beyond which statistical analysis becomes appropriate. This means that the frequency spectrum can be approximated by that of a Gaussian white noise process. Beyond f_{schr}, the distance between two resonances Δ(f_{N}) becomes so small that in average at least three resonances will fall within the average bandwidth (Bf_{N}) of one resonance, and separation of the resonances becomes almost impossible.

$${f}_{schr} = 2000 \sqrt{\frac{{T}_{60}}{V}} \qquad 2.5$$

For typical listening rooms fschr lies in the range 100-150 Hz, the average bandwidth of the resonances amounts to 4-5 Hz, and the typical dynamic range of the frequency spectrum is ±15 dB. In FIG. 2.4 is shown a low frequency magnitude spectrum of an impulse response. Clearly, the resonances cause visible irregularities, and at frequencies below at least 200 Hz it seems like the peaks can be pointed out individually (fschr according to eq. 2.5 is 141 Hz).

Room Acoustics in a Brief Perspective.

It is crucial to understand that the positions of loudspeaker and listener do not change the pattern of room resonance frequencies, but they do influence how the resonances are excited and perceived.

A picture like the one in FIG. 2.5 can be drawn revealing and separating time-frequency regions which deserve individual attention. In the upper left corner we have the region of separable reflections and modal resonances that can be pointed out individually. This region is presumably the one in which the human hearing finds most unpleasant artefacts. In the lower right corner however both the time and frequency domains are dominated by non-separable elements which can be described as stochastic processes, i.e. only an overall dependence on the room acoustic properties.

The room size (volume) is of particular interest when characterising and modelling the time and frequency phenomena, since it outlines the limits in the combined domain. Increasing the volume moves tₛₜₐₜ upwards and f_{schr} downwards and vice versa. To exemplify, in large volume concert halls it may simply not be relevant to discuss room modes and resonances—but indeed the number of individual reflections can be great. In a small room, perhaps only the first two to four reflections can be separated, but in return room resonances may be individually dominant up to several hundreds of Herz.

The perhaps most obvious way to acquire information of the room acoustics is to consider a sound transmission path—from a sound is emitted from some well defined source in the room at position Pₛ until the sound is received at position Pᵣ. Relating the sound received to the one emitted, it is possible to find out exactly how the room impacts sound from Pₛ to Pᵣ. This consideration seems reasonable since we are dealing with a loudspeaker positioned at Pₛ and a listener at Pᵣ. This consideration is referred to as a point-to-point scenario—in a mathematical sense. Of course, the sound emitted from the loudspeaker does not come from a single point in space (e.g. due to distance between driver units), so the real-world interpretation of the point-to-point scenario must be relaxed somewhat. In the receiver end though, it is still valid to consider Pr as a point provided the receiver is a single microphone (if a human being with two ears, the assumption obviously does not hold).

The MLSSA acoustics measuring system is capable of acquiring such transmission path information. By emitting through a loudspeaker a Maximum Length Sequence (resembling a random white noise sequence) sₛ(t) and measuring by a microphone the sound pressure sᵣ(t) at the desired point, it is able to calculate the transmission path impulse response hₛᵣ(t) by cross correlation.

The impulse response is a measure telling what is experienced at the receiving position Pᵣ when ideally a perfect sound impulse d(t) with infinitely short duration and infinite bandwidth is emitted from Pₛ. Clap of hands or pistol shots come close to this ideal impulse. Such a signal is vulnerable to noise however, and that is why the cross correlation technique was devised and is widely used. Actually, the impulse response hₛᵣ(t) holds information on three items affecting the sound,—the loudspeaker, the room, and the microphone. The effect of these items may or may not be separated. In general, the microphone contribution is neglected due to its usually large frequency bandwidth compared to the desired audio bandwidth. eq. 2.6 shows the items of impact as individual impulse responses contributing to the received signal sᵣ(t) in terms of time domain convolutions. Replacing sₛ(t) by d(t) we simply get the entire system (or transmission path) impulse response hsr(t).
sᵣ(t)={h_{loudsp}(t)⊕hᵣₒₒₘ(t)⊕h_{mic}(t)}⊕sₛ(t) 2.6

The MLSSA measures absolute sound pressure and is used for room acoustics acquisition in this work. It is a discrete-time system meaning that the response h(t) is actually represented as a sequence of samples denoted h(n).

Impulse Responses and Transfer Functions.

An impulse response h(t) is a continuous time domain measure. For computer based measurement the output of course is discrete.

The transfer function is the frequency domain equivalent to the impulse response. The relationship is the Z-transform, see eq. 2.7, and usually (for practical purposes) H(z) is also sampled giving a finite number of complex values of H(z). Z-transformation of eq. 2.6, with sₛ(t) replaced by a discrete-time version of d(t) and ignoring the very small impacts from the microphone, leads to eq. 2.8 where the convolutions have turned into multiplications.

$$\begin{matrix}H ( z ) = {\sum }_{n = 0}^{∞} h [ n ] \cdot {z}^{- n} & 2.7 \\ {H}_{sr} ( z ) = {H}_{loudsp} ( z ) {H}_{room} ( z ) {H}_{mic} ( z ) & 2.8\end{matrix}$$

Digital Signal Processing Techniques for Correcting Algorithm Design. Transfer Function Decomposition and Hilbert Transform.

The Z-transform H(z) of a measured room impulse response h(n), although non-parameterised, can be modelled by a generalised digital IIR filter as in eq. 3.1. Essentially, the generalised systems modelling encompasses both numerator and denominator polynomials. The roots aⱼ in the numerator symbolise the zeros in the transfer function inside the unit circle and the bⱼ are the zeros out-side the unit circle. Correspondingly, cᵢ denote the inside of the unit circle poles of the transfer function and di the outside poles.

$$H ( z ) = \frac{{\sum }_{j = 0}^{M} {β}_{j} {z}^{- j}}{1 - {\sum }_{i = 1}^{N} {α}_{i} {z}^{- i}} = \frac{{\prod }_{j = 1}^{{M}_{i n}} ( 1 - {a}_{i} {z}^{- 1} ) {\prod }_{j = 1}^{{M}_{out}} ( 1 - {b}_{j} {z}^{- 1} )}{{\prod }_{i = 1}^{{N}_{i n}} ( 1 - {c}_{i} {z}^{- 1} ) {\prod }_{i = 1}^{{N}_{out}} ( 1 - {d}_{i} {z}^{- 1} )} \qquad 3.1$$

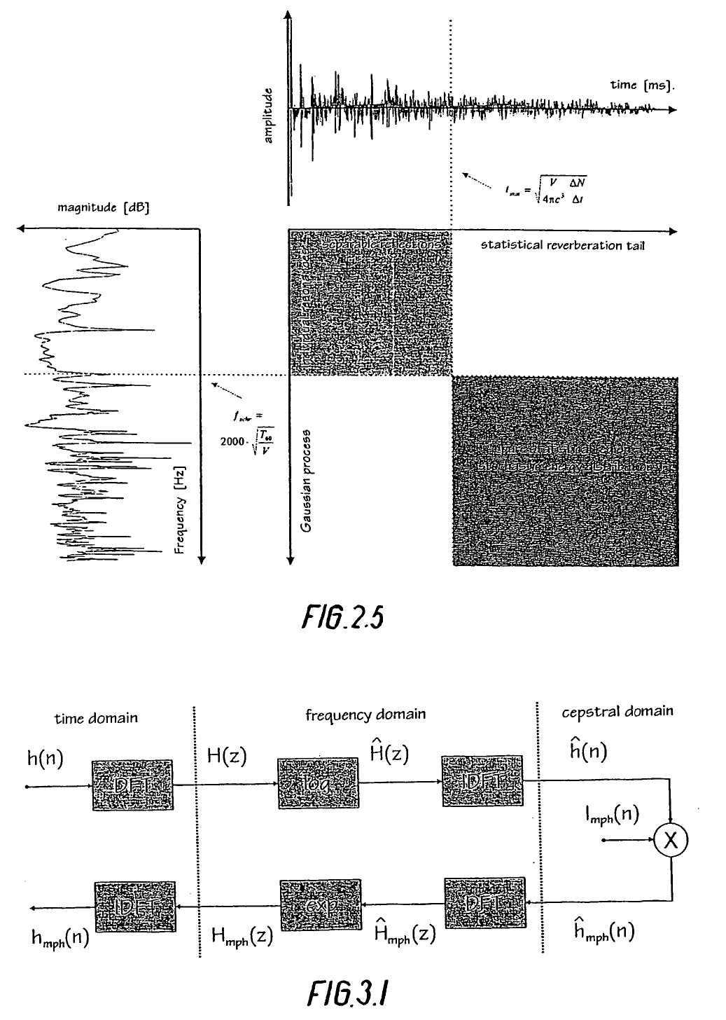

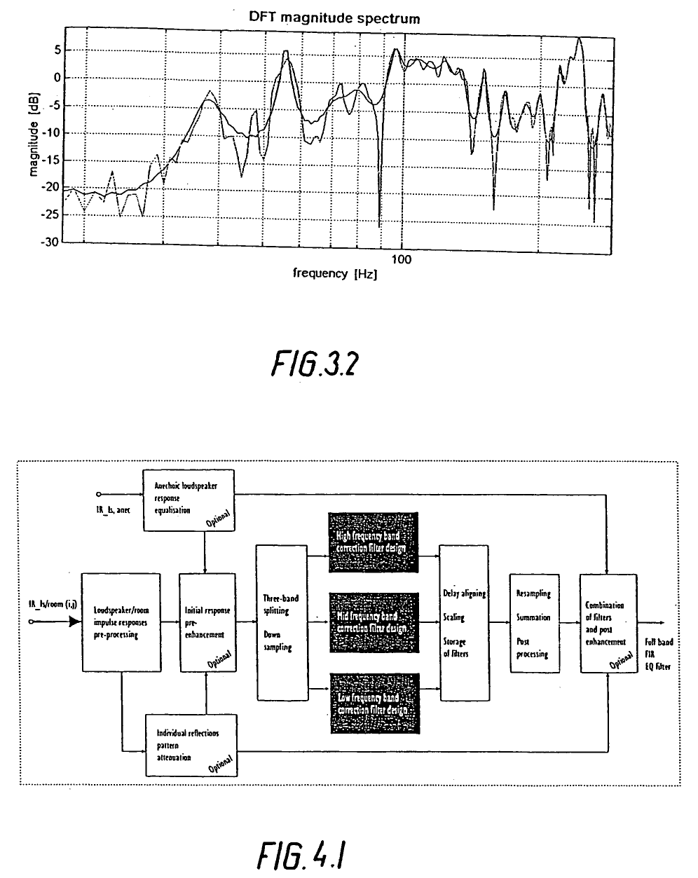

Through decomposition, any transfer function H(z) can be split into a product of a minimum phase part, an allpass part, and a pure delay (sometimes Hₐₗₗₚₐₛₛ(z) also contains the delay Z⁻ⁿ). The minimum phase part consists of all the poles, the natural “inside” zeros (aⱼ), and any “outside” zero bⱼ mapped to the inside with magnitude 1/r(bⱼ), call them b′ⱼ. The allpass part consists of the original “outside” zeros bⱼ and poles cancelling out the artificially introduced zeros b′ⱼ, these poles are denoted by a′ⱼ. All possible magnitude information of H(z) then is held in Hₘₚₕ(z), whereas the magnitude of Hₐₗₗₚₐₛₛ(z) as defined will always be unity. It can be shown that the minimum phase thus defined and the magnitude in a transfer function are unambiguously linked together. Separation of minimum phase systems and allpass systems can be accomplished by employing homomorphic deconvolution. The minimum phase part of a response h(n) can be extracted by first forming the complex cepstrum, then deleting any non-causal information in this domain, and finally by reverse operations turning back to the time domain, using the steps in FIG. 3.1.

Inverting a mixed phase system hₘᵢₓ(n) leads inherently to instability. The interesting thing is however that an unstable but causal system also can take the form of a stable but non-causal system, so by allowing non-causality the correction of maximum phase systems actually does become possible. The excess phase in, a room impulse response can then be equalised by introducing a delay. To account for all the excess phase, ideally the non-causality thus imposed should last infinitely long which is of course not possible. From sheer practicality, equalising excess phase is then a compromise between the degree of correction and the amount of delay which can be tolerated. Optimally, when equalising hₘₐₓ(n) in a point-to-point scenario, no artefacts are present in the correction delay part but the non-causal correction will introduce artefacts whenever the reproduction system is altered even slightly. The artefacts can be audible, e.g. as pre-echoes and/or pre-reverberation, which is extremely annoying.

Parametric Transfer Function Modelling.

Modelling a transfer H(z) in a parametric way can be useful in equalisation, particularly when the phenomena in H(z) are in good accordance with the technique leading to the parameterised model. In general, taking a starting point in eq. 3.2, parameterised models is classified in three categories, the MA (moving average) models, the AR (autoregressive) models, and the ARMA (combination of MA and AR) models. A moving average model emerges when one or more bⱼ is different from zero and all aᵢ are zero saying that no denominator polynomial exists and H(z)=B(z). Hence only modelling by zeroes is possible, and since zeroes represent dips in the frequency magnitude spectrum, MA modelling is probably not the best way to model resonances.

$$H ( z ) = \frac{B ( z )}{A ( z )} = \frac{{\sum }_{j = 0}^{M} {b}_{j} {z}^{- j}}{1 + {\sum }_{i = 1}^{N} {α}_{i} {z}^{- i}} = \frac{{b}_{0} + {b}_{1} {z}^{- 1} + … + {b}_{M} {z}^{- M}}{1 + {a}_{1} {z}^{- 1} + … + {a}_{N} {z}^{- N}} \qquad 3.2$$

When the B(z) polynomial has coefficients bⱼ=0 (apart from the constant b₀), H(z) is an autoregressive function H(z)=b0/A(z). Here we have roots in the denominator causing peaks in the magnitude spectrum. This is more like what we are looking for since these peaks could well resemble the modal resonance peaks in the measured transfer function. One way to establish an autoregressive model is through Linear Prediction. Linear prediction assumes a H(z)=1/A(z) model and will attempt to find the A(z) polynomial coefficients ai so that the error between the model and the measurement is minimised in the least squares (LS) sense. The procedure assumes that a particular sample of say an impulse response h(n) can be formed (or predicted) as a linear combination of previous samples.

One great thing about the AR approach is that when using the model for straightforward inverse equalisation filter design, the equalisation filter G(z) becomes an FIR filter. FIR filtering is equal to moving averaging, it has finite impulse response, and it is inherently stable. AR modelling is attractive then because of its ability to capture the phenomena in the measured transfer function that we want to address, and because it produces simple and stable and minimum phase inverse filters. FIG. 3.2 shows an order 48 LPC modelling of a low frequency room transfer function.

Spectral Inversion, Smoothing and Regularisation.

Without any modifications, a pure inversion of H(z) is generally not possible without tolerating considerable delays. If equalisation of minimum phase only can be accepted though, we can decompose H(Z) and invert Hₘₚₕ(Z). For the reasons discussed previously even this is probably not a good idea in practical correction systems, but a feasible approach could be to smooth the spectrum, i.e. perform an averaging in 1/N octave bands. This way, narrow band effects are averaged out and in fact a time domain smearing is imposed also. Now it is no problem finding an inverse spectrum of the smoothed H(z). When such smoothing is done, any phase information is lost initially. However, by using the Hilbert transform, we can derive a completely new phase part and construct a new complex Fourier transform from the smoothed magnitude part. Turning back into the time domain, and allowing a small delay (necessary to account for a slight non-causality due to the smoothing), we have a minimum phase equaliser based on a smoothed transfer function.

If no smoothing is allowed (or perhaps in a combination), so-called regularisation of a transfer function subject to inversion can be done. Regularisation, referring to eq. 3.3, will suppress the dip (zeroing) effects with a desired amount determined by the ζ constants, and hence the inverse transfer function, G(z), will not suffer from equal size peaks relative to the initial dips. This can be advantageous when we want to design low frequency equalisation by spectral inversion instead of using the AR modelling. Still though, the inversion should be based on a minimum phase decomposed version of H(z).

$$G ( z ) = \frac{1 + {ρ}_{1}}{H ( z ) + {ρ}_{2}} \qquad 3.3$$

Warping the Frequency Scale.

Frequency warping is a way to redistribute the attention on the frequency scale. For example, more focus can be put on the low end of a frequency band at the expense of the high end detail. Actually, frequency warping is a conformal mapping where the normal delay element z⁻¹ in discrete-time systems is replaced by a first order allpass filter D(z) as in eq. 3.4.

$$D ( z ) = \frac{{z}^{- 1} - λ}{1 - λ {z}^{- 1}} \qquad 3.4$$

Hence, we have a nonuniform-resolution frequency representation of H(z). This can be very advantageous when trying to reflect the mechanisms of the human hearing, where a logarithmic-like frequency dependent frequency resolution is observed. Choosing λ rightly (0.7-0.75), will produce a frequency scale resembling that of the Bark scale. Now, impulse responses can be warped, equalisation filters can be determined in the warped domain, and the equalisation filter response can be dewarped (same procedure, just using negative λ). The drawback is however that using D(z) as above instead of z⁻¹ turns FIR filters into IIR filters, so stability is not automatically ensured (particularly for large filter orders), and the equalisation filters have infinite impulse responses which must be truncated (if not in fact the equalisation is carried out in the warped domain). These WFIR filters can represent a more adequate allocation of filtering capacity in acoustical applications.

Early Reflections Attenuation and Diffusion.

A technique has been developed for attenuating early strong reflections in a room impulse response h(n). The technique qualifies by the fact that it does not try to deconvolve the reflections, that would be alarming from a position sensitivity point of view. Instead it attenuates each reflection and anything else in a small time span around the reflection. The algorithm is not extremely complicated and can easily be incorporated in a room acoustics correction framework. By the techniques described in the above sections, only frequency domain effects are addressed directly and we can just hope that the actions will also have a positive effect in the time domain. The reflections attenuation algorithm addresses annoying time domain effects. Forming the algorithm involves the steps below, and it is a quite new way to address room acoustics correction from a practical viewpoint.
A segment c(n) of length t_{c} covering the early reflection is cut out of h(n)
The magnitude spectrum of c(n) is smoothed getting G(z)
G(z) is inverted and reverse transformed to g(n)
g(n) is causalised into g_{caus}(n) by a delay t_{caus}
g_{caus}(n) is multiplied with a special window

As an alternative to the reflections attenuation, in order to render the first strong reflections inaudible as separable phenomena, a diffusion filter (also a new technique devised by the author) could be applied. A small sequence (a few milliseconds in length) of white noise, which is exponentially weighted to decrease in average to 10%, is convolved by the measured impulse response. The early strong reflections are then smeared in time and the early part of the response will contain more energy, so the Clarity index will increase but DR will probably not since the direct sound is not amplified. This situation would resemble that of having many reflections of relatively low amplitude close to each other. Actually, their amplitude may be fairly high but due to the small spacing their individual contributions are probably rendered inaudible.

Excess Phase Equalisation.

Since hₐₗₗₚₐₛₛ(n) holds no information about the frequency magnitude, we can convolve the initial response by this and only the phase is changed. In fact, it can be shown that performing the convolution as given in eq. 3.5 results in a complete removal of excess phase. So only a minimum phase version of h(n) is left. Of course for infinitely long sequences, eq. 3.5 cannot be determined, so one will have to choose a finite length of the causalisation. Also practical reasons can dictate such a restriction, e.g. introducing delays of just a few hundred milliseconds destroys synchronisation in a combined audio/visual reproduction. This reduces the amount of excess phase that can be corrected for. Also to minimise the risk of pre-echo and pre-reverberation effects, the causalisation should probably be chosen fairly small.
hₘ(n)=h(n)⊕hₐₗₗₚₐₛₛ(−n) 3.5

The object of the invention is to improve a loudspeakers behaviour in relation to the acoustic parameters of the room the loudspeaker is placed in the room.

The object is fulfilled by a method defined in the introductory part of claim 1, that is characterized in the following steps:
a) the measured impulse responses are pre-processed by an algorithm and weighted
b) the output from the pre-processing algorithm is split by an algorithm and adapted to at least two frequency bands using cross-over filters and down sampling
c) the output from the band splitting algorithm is fed to at least two frequency band correction filter algorithms
d) the output from the band correction filter algorithms are fed to a delay and amplitude aligning design algorithm
e) the output from the aligning algorithm is fed to a post processing algorithm
f) storing and using the output from the post processing algorithm to equalise in real time a sound source that is fed to the amplifier.

As stated in claim 2 that the output from the pre-processing algorithm is divided into typically three frequency bands, said tree bands are low-, mid- and high frequency bands respectively, a more adaptable correction belonging to certain aspects of the acoustic behaviour in the frequency domain i_{d} obtained.

It is expedient if as stated in claim 3 that the output from the pre-processing algorithm is used as an input in a pre-correction algorithm, said pre-correction algorithm having at least one more input adapted to receive an output from one ore more optional circuits representing certain acoustic impacts on a sound received in the listening position and said pre-correcting algorithm having an output that is fed to the frequency band correction filter design algorithm.

In this way it is possible to adapt the overall equalising, not only to the physical parameters in a room, but also to other parameters, f. inst. as stated in claim 4, that one of the optional circuits represents parameters measured from a loudspeaker under ideal conditions in an anechoic room or as stated in claim 5 that one of the optional circuits represents parameters derived from psycho acoustic conditions.

Experiments has shown that an even better equalising is obtained if the method is performed so that in the first 30 ms the reflections in the measured impulse response are attenuated more strongly than in the rest of the impulse response as outlined in claim 6.

In order to secure that all signals processed when leaving the equalising process are timely in order, its an advantage if as stated in claim 7 that the aligning algorithm comprises aligning functionality for synchronising the output from the band filters, or as stated in claim 8, that that the aligning algorithm further comprises scaling and summation functionality.

Finally, as stated in claim 9, that the correction is performed in respect of certain part of a room in which the listener is placed, it is possible to choose how accurate a user wants the equalising.

In other words if the user want a very high accuracy, then he must chose a very little part or area of the room where the equalising is optimal and vice versa.

As mentioned, the invention also relates to a use.

This use is defined in claim 10.

In the following the invention will be more clearly explained in connection with the accompanying drawings on which

FIG. 1.1 shows in principle how a real audio event should be presented after a storage,

FIG. 1.2 (left) shows a simplified block diagram on how to design an equaliser and (right) how the equaliser is used,

FIG. 2.1 shows an example showing reflections from sound emitted by a loudspeaker in a room,

FIG. 2.2 shows an impulse response measurement from a listening room,

FIG. 2.3 shows a curve illustrating modal resonances in 5 Hz bands,

FIG. 2.4 shows a low frequency magnitude spectrum,

FIG. 2.5 shows a diagram explaining time frequency regions deserving individual attention.

FIG. 3.1 shows a diagram in which a time domain function is transformed and reversed,

FIG. 3.2 shows an order 48 LPC modelling of a low frequency room transfer function,

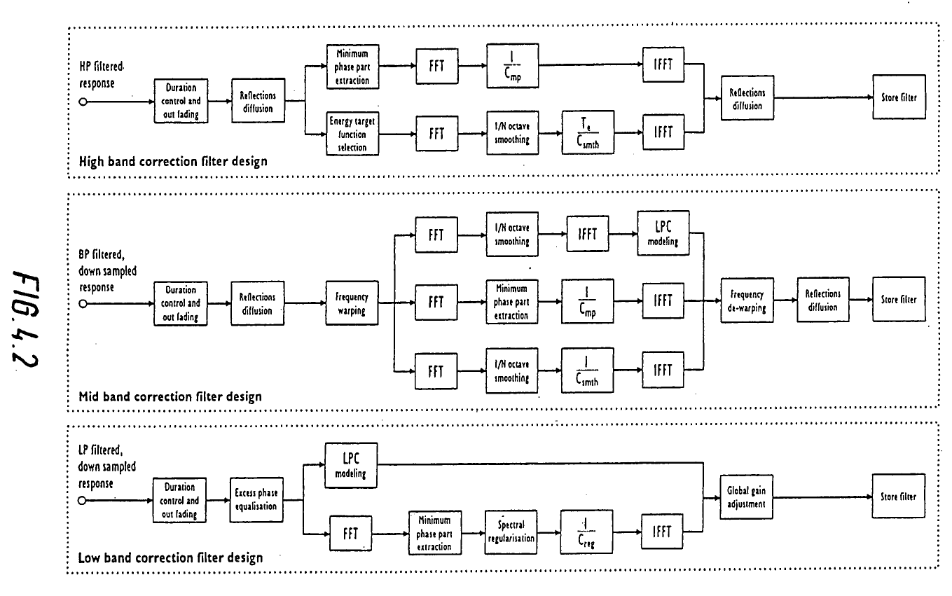

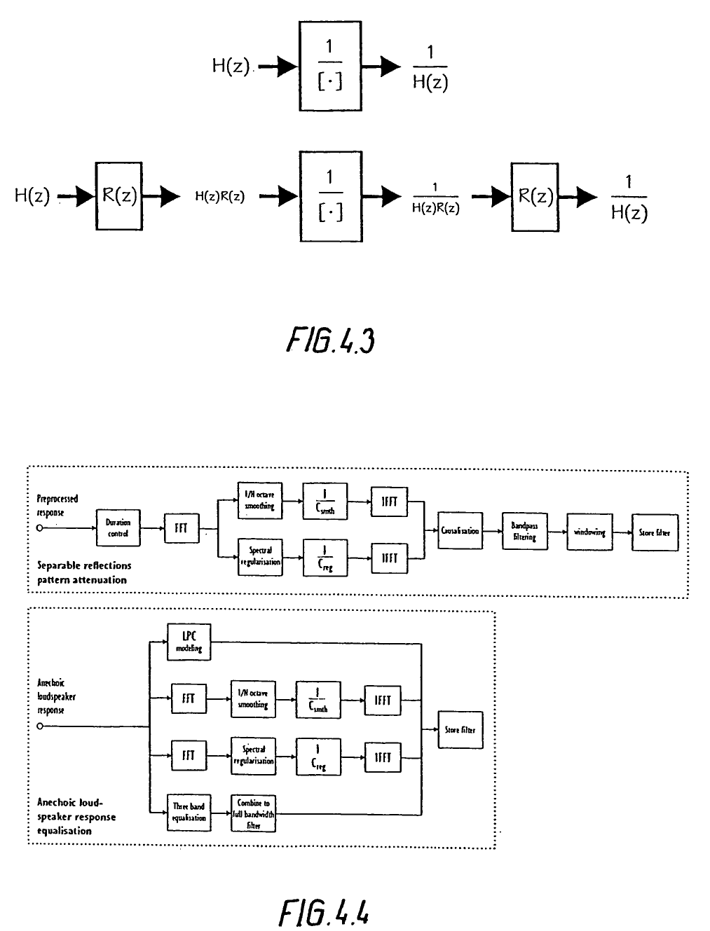

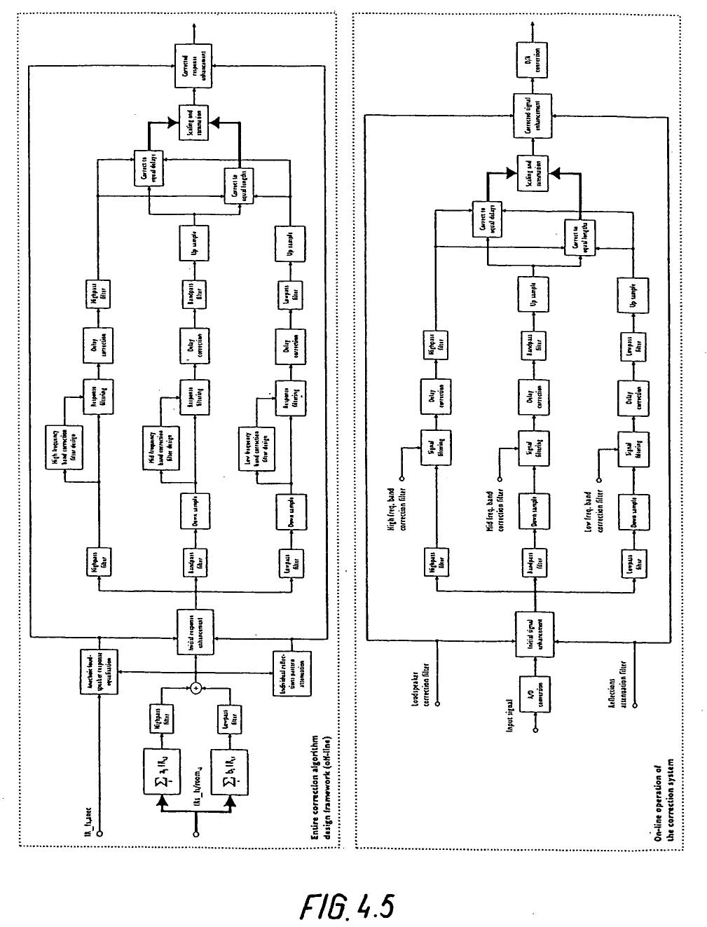

FIG. 4.1 shows a block diagram illustrating the various algorithms used according to the invention,

FIG. 4.2 a detailed block diagram of the filters according to FIG. 4.1,

FIG. 4.3 shows a diagram transfer function used in the algorithms in FIG. 4.1

FIG. 4.4 a detailed block diagram of two optional blocs according to FIG. 4.1,

FIG. 4.5 shows a block diagram two possible configurations of the correction system according to the invention,

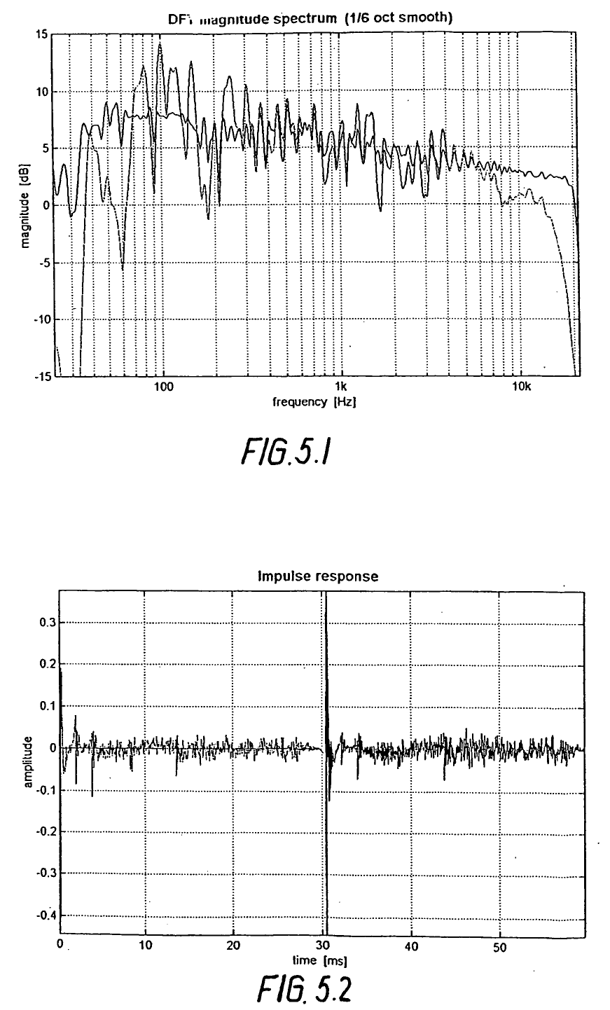

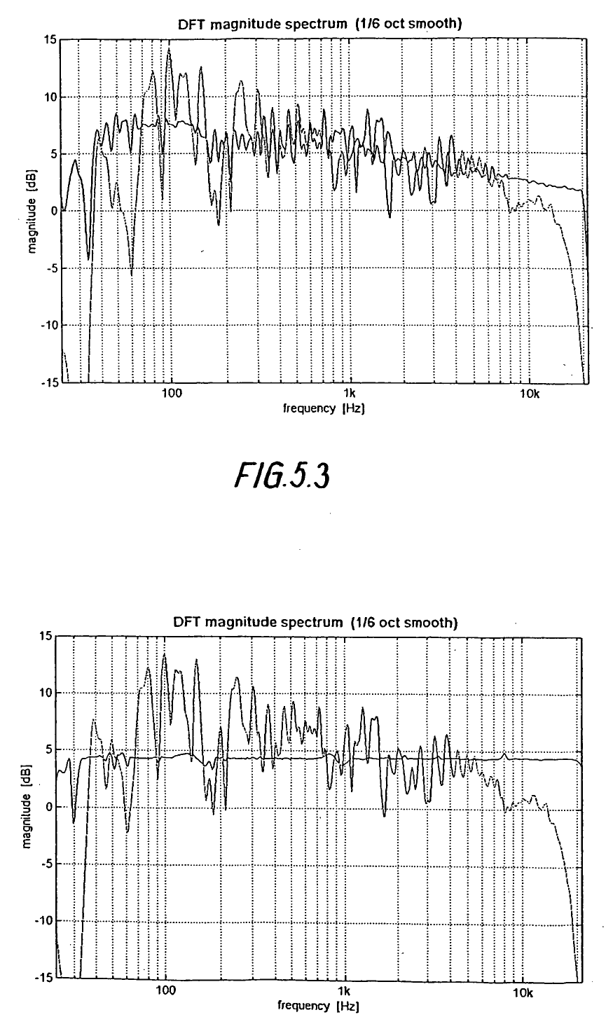

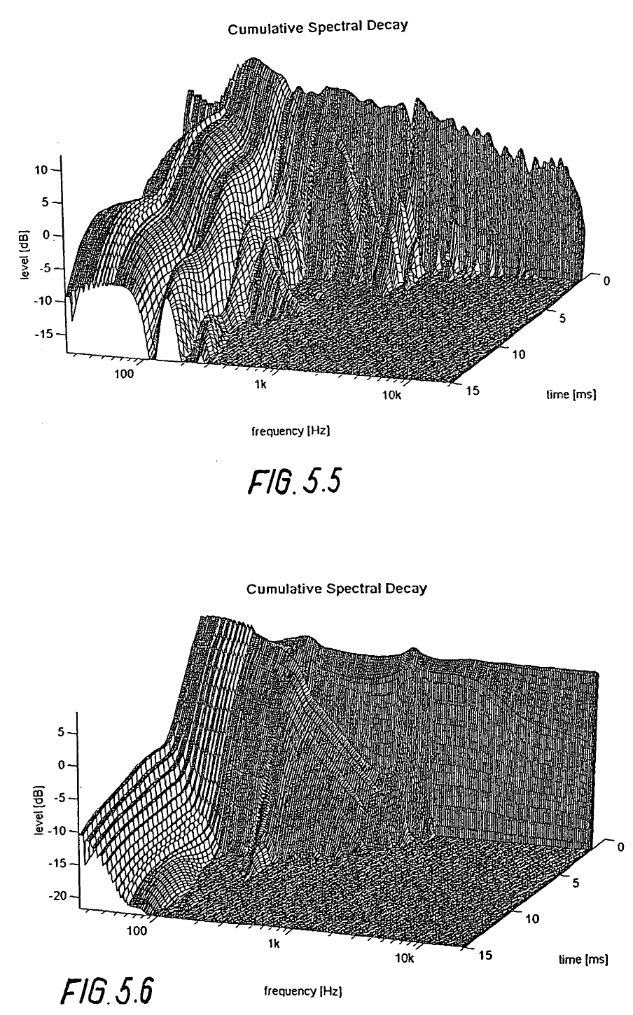

FIG. 5.1 shows a DFT magnitude spectrum showing the performance of the algorithm according to the invention

FIG. 5.2 the correction algorithm having reflections attenuation function enabled

FIG. 5.3 shows DFT magnitude spectrum showing the performance of the correction algorithm under use of the reflection attenuation function,

FIG. 5.4 shows a DTF magnitude spectrum of the optimised performance of the equaliser according to the invention,

FIG. 5.5 shows a cumulative spectral decay before loudspeaker correction, whereas

FIG. 5.6 shows a cumulative spectral decay after correction.

In FIG. 4.1 is shown a schematic of the framework set up for loudspeaker/room correction design. The main functions are pre-processing, band splitting, three-band correction, and post processing, and the contents of these building blocks are explained in detail in the following sections. The room acoustics correction design framework is been set up in a way to allow flexibility in all parameters. Although the design framework takes a starting point for correction in a single transmission path impulse response, this may be composed by weighted averages of more responses. In the low frequency range where considerable peaks occur, a frequency resolution around 2 Hz will suffice, but straightforward implementation with an FIR filter requires around 22,000 filter coefficients to obtain this resolution. Today this is still too heavy for standard signal processors. The high resolution is only required at low frequencies however so a band splitting and down-sampling technique is obvious to start out with. In order to relax the demands to the three-band correction design or to impose specific time domain corrections, the initial response can be modified by auxiliary functions, see section 4.6.

In the first step, an initial input response is derived from measured impulse responses. The initial response can be based one single measurement, or more impulse responses hᵢ(n) may be averaged (simply as scaled sample-by-sample addition) using arbitrary weights—within the entire bandwidth or if preferable just below some frequency f_{c}_{_{—}}_{avrg}. This allows for inputting a smoothed response to avoid or reduce position sensitivity at high frequencies or to implicitly make a better estimation of the perceived effects from low frequency resonances. A combination is also allowed, i.e. below f_{c}_{_{—}}_{avrg} the input response can be the ave-rage of responses from multiple sources to a single receiver position and beyond f_{c}_{_{—}}_{avrg} the single measurement will rule. Still the point is to design a correction for one transmission channel at a time.

The initial input response is then split into three bands allowing for dedicated frequency dependent correction such as room acoustics and psychoacoustics point towards. The band splitting uses linear phase FIR filters in order to minimise any audible effects from these crossover filters. Four frequencies must be input: The low and high cut-off frequencies and the two crossover frequencies. It is reasonable to choose the lower crossover frequency in the neighbour-hood of the Schroeder frequency of the room and the upper crossover frequency 6-7 times higher where position sensitivity sets the agenda. For the high band the initial sampling rate is maintained but for reasons of convenience and due care for processing power the mid and low bands are resampled at rates 3-4 times the crossover frequencies.

In each of the three bands, the duration (length in samples) of the response subject to equalisation can be set, thus imposing an inherent smoothing due to decrease in frequency resolution. This smoothing could turn out to be beneficial, and shortening the response duration would certainly reduce the need for processing power. There are reasons to believe that the higher the frequency, the shorter response is necessary.

The low frequency channel is restricted to approximately the Schroeder frequency typically about 150 Hz, pointing towards a sampling frequency below 1 kHz. In this case, 2 Hz frequency resolution typically requires less than 500 taps of a filter. A robust inverse filter design method can be based on an AR model (all pole) of the input response. The inverse filter is based on the LPC technique shortly described in section 3 and the order is variable. This compensation method is attractive because;
it particularly serves to suppress peaks,
the equalising filter is an all-zero one,—stability is always ensured, and
the equalising filter is automatically minimum phase.

Another way of creating an equalisation filter also incorporated is to simply invert the complex spectrum. Here however the spectrum subject to a regularisation before inversion in order to let the peaks weigh more than dips of the same magnitude. This method does not ensure minimum phase filters (only if the magnitude spectrum is used), and it tends to be inferior to the LPC method when it comes to robustness. Finally, together with any of the two magnitude related methods, any amount of excess phase in the input response can be compensated for using a mirror convolution of the excess phase response—at the expense however of a delay equal to the length of the excess phase response.

As described, the lower crossover frequency should be selected around the Schroeder frequency, and since position sensitivity is already a problem at a few times f_{schr}, smoothing through a filter bank, with resolution about 0.5-1 Bark, could be motivated by psychoacoustics. In the frequency range above 500 Hz this resolution corresponds roughly to ⅙-⅓ octave. The Bark scale is more related to human sound perception (including timbre). In the mid frequency band the following options are implemented:
AR modelling and inverse filter design by the LPC technique (or)
minimum phase magnitude spectrum inversion
pre-smoothing
pre-warping
reflections diffusion

The last option is a way of reducing the audibility of early strong reflections by convolving the response with a short (5 ms) exponentially weighted white noise response. This “diffusion” filter tends to blur the separable reflections somewhat but does no good for reverberation time and clarity. Again, the AR model order is variable as are the smoothing factor (from 1 octave to 1/24 of an octave) and the warping factor allowing for putting more attention to the lower part of the mid band if enabled.

In the high frequency range the equalisation should preferably be reduced to correction of the tonal balance in bands of width ⅙ to ⅓ octaves. Note that the psycho acoustically motivated Bark frequency scale is close to ⅓ octave, above 500 Hz. The application of an FIR filter inherently imposes a frequency smoothing caused by the window applied to limit the length of the filter response. In the high frequency band the following options are implemented:
minimum phase magnitude spectrum inversion
pre-smoothing
reflections diffusion

As well as in the mid frequency band, the reflections diffusion can be enabled here too, and three alternatives of target functions are available:

One with a flat frequency spectrum and two with slightly decaying spectra (4 dB and 7 dB per decade respectively). The AR modelling method is not well suited for this band since it would focus too much on the peaks, but no narrow band equalisation is required or even desired here. The functional blocks of the entire three-band equaliser are shown in FIG. 4.4.

To improve the correction performance, two more options are available. Both options (if enabled) alter the initial response to the three-band equaliser, thus the three equalisation filters operate on the altered response, and the output of the three-band equaliser must be corrected once again. Going into the frequency domain and simplifying the three-band equaliser functionality to a blind inversion (which of course it is not), the concept is shown by FIG. 4.3. The input transfer function H(z) subject to correction must end up with 1/H(z) regardless what happens on the way.

The linear operations representing the auxiliary options denoted R(z) must consequently also be applied after the inversion.

The three-band equaliser mainly works in the frequency domain but to control the individual reflections in the input response it is necessary to operate in the time domain. The addressed reflections sequence is cut out, frequency transformed, and either subject to regularisation or smoothing before inversion to avoid a too sensitive modification of the reflections. By this modified deconvolution technique, up to 30 ms of the response is attenuated by 6-12 dB by a reflections attenuation filter. It is not desirable to cancel out the reflections pattern entirely due to the position sensitivity issue and also because of the dubious subjective quality of a response with no energy at all in the first 15-30 ms. Both the regularisation and the smoothing call for a post causalisation (introducing a delay), and finally the reflections attenuation filter is band pass filtered to restrict its operation to the band 100-1000 Hz—also to reduce the complete cancellation especially at high frequencies, see FIG. 4.4. The reflections attenuation algorithm is described in more detail in section 3.

For some reasons it may be advantageous to pre-equalise the loudspeaker and to include that equalisation filter in the algorithm operating on the entire input room response, e.g. when specific modifications of a loudspeaker are desired. Four ways of equalising the loudspeaker are proposed, see FIG. 4.4.

In FIG. 4.5 are shown the two possible configurations of the correction system, the “off-line” configuration where equalisation filters are designed based on measured responses and stored, and the “on-line” real-time configuration in which electrical signals are down sampled, corrected based on the stored filters, and resampled and added to form the final corrected signal. In the “off-line” configuration, after correction design in each band the correction filters are scaled and time aligned due to the possible delays introduced, and finally stored in filter banks. Also, the three filters are resampled up to the initial rate and put together into one FIR filter—primarily for evaluation purposes. A fade out window is applied (also for evaluation purposes), and the final filter is scaled in order to let a corrected response have the same energy, in the band 250 Hz to 5 kHz, as the initial response.

Examples on the Room Acoustics Equaliser Performance.

The response input to the band splitting/down sampling is synthesised as the equally weighted sum of two responses below 150 Hz (stereo speakers and one measurement point), and above 150 Hz no averaging is done. This averaging is introduced in order to better capture the general resonance phenomena instead of just the ones separately invoked by the two loudspeaker positions. Slightly less accurate correction of the individual transfer functions is the cost however. Finally, the response is scaled until its total energy equals 1.

The cross-over frequencies of the three band equaliser were set to 150 Hz and 900 Hz, respectively. The Schroeder frequency is 95 Hz so above 150 Hz no individual resonance phenomena should be found, and the 900 Hz is chosen because of the mid frequency band corrections that are too delicate to be applied for higher frequencies. In fact any crossover frequency between 700 Hz and 1.5 kHz would probably suffice, however the cross-over of the particular algorithm selected as described above turned out to be 900 Hz. Lowest and highest correction frequencies are set to 25 Hz and 22 kHz respectively. Down-sampling is performed to give new Nyquist frequencies at 1.5 the cross-over frequencies (these being 422 Hz and 2430 Hz) which equal down sampling factors of 144 and 25.

The cross-over filters are all linear-phase FIR filters, and the orders have been chosen from the criterion that when adding down sampled bands of an ideal impulse, the result should come as close as possible to an unfiltered ideal impulse. Also, the slopes of LP and HP filters (for both cross-over frequencies) should be approximately the same. This results in low pass filter orders (taps) of 18, 28, and 18, and high pass filter orders of 28, 84, and 560.

In the low frequency band it is chosen to calculate an AR (autoregressive) model describing the transfer function. This model, 1/A(z), consists of poles only and hence describes well the modal resonance peaks. The AR model is found by Linear Predictive Coding (LPC), and the number of coefficients in the A(z) polynomial is set to 48 resembling the effect of 24 second order poles. It is assumed (and verified) that 24 such poles should be sufficient to model the separable resonances up to 150 Hz. Using the A(z) polynomial as an FIR equalisation filter will remove the characteristic peaks in the transfer function with-out also undesirably putting energy into the natural dips in the transfer function. To compensate for the loss of energy through this peaks attenuation, the entire low band is amplified 1.5 dB. In the low band, equalisation operates on the whole input response of 500 ms yielding an inherent smoothing of 2 Hz.

In the mid band only the first 150 ms of the input response is used (this imposes a maximum frequency resolution of 7 Hz which actually is desirable since we do not want to pay as much attention to narrow band peaks phenomena here as in the low band), and also here the AR modelling technique is applied. Using the frequency warping technique as described in section 3, it becomes possible to focus more on low frequencies, and using a warping factor of 0.72 the LPC mathematics pays more attention to the band 150-400 Hz than to frequencies above 400 Hz. It is assumed that as frequency increases the transfer function phenomena easily modelled by AR poles also become less, i.e. there could be good reasons for combining the AR modelling and the frequency warping.

The high frequency band deals with the first 50 ms yielding a frequency resolution of 20 Hz (which complies nicely with the fact that only relatively broad-band equalisation should be done here). In this band a straightforward spectrum inversion is applied but prior to inversion the input response spectrum is further smoothed in quarters of an octave. The smoothing removes any phase information, it is restored however using the Hilbert transform relations. After inversion the spectrum is weighted by a slightly decaying function (−4 dB from 1 kHz to 10 kHz) resembling the natural high frequency attenuation in room impulse responses, and finally transformed back to a time domain FIR filter.

In FIG. 5.1 the algorithm performance is shown. Grey plots show the response input to the correction design framework and its spectrum, and the black curves show the corrected impulse response and spectrum, respectively. Particularly in the spectrum plots it is easy to see the correction effect.

Now, the reflections attenuation capability is investigated. The input response is once again the low frequency position averaged one but now, before the three-band equaliser, the reflections attenuation function is enabled. For the first 10 ms the reflections are set to be reduced (but as described in section 3 not totally removed) about 8 dB, and that clearly shows on FIG. 5.2. Letting the enhanced (reflections attenuated) response through the three-band equaliser does not affect the resulting frequency magnitude spectrum much, see FIG. 5.3. It still looks fine and pretty much as the one for the initial algorithm which is quite in accordance with expectations since the same algorithm parameters are used and the output response is post corrected with the reflections attenuation filter as it should according to the correction design framework.

Alternative Uses of the Correction Design Framework.

The purpose of this algorithm is to show that whenever subjective performance is not an issue it is possible to configure the design framework to come up with very accurate corrections. No averaging is done for the input response, neither for listening positions nor for the loudspeaker positions at low frequencies. For all three bands the processed response length is 500 ms. In both the low and mid band very detailed AR modelling is applied, in the low band using 120 coefficients. In the mid band no smoothing and pre-warping are done, and as much as 288 LPC coefficients are used. Also, in the high band smoothing and decaying target functions are omitted. So from a signal processing point of view, the actions taking place in the three bands more or less resemble that of a total spectral inversion (only in a controlled and robust manner) due to the large number of LPC coefficients—but it happens in a minimum phase way. The spectral inversion is trivial apart from the excess phase, that is why the three-band technique tuned to higher accuracy is used. The objective performance is outstanding as shown in FIG. 5.4.

The correction design framework is also well suited to equalise loudspeakers alone. An anechoically measured speaker has been subject to the same optimised parameters of the correction algorithm as were used in the room correction set up. FIGS. 5.5 and 5.6 show the cumulative spectral decays before and after correction. The equalisation is quite prominent in both domains.

1. Method of digitally equalizing sound from loudspeakers placed in a room having a combined loudspeaker/room transfer function, said method comprising placing a microphone in the room, emitting one or more pulses form a loudspeaker through an amplifier and measuring the impulse response in a desired listening position, said method is characterized in the following steps:
a) the measured impulse responses are pre-processed by an algorithm and weighted
b) the output from the pre-processing algorithm is split by an algorithm and adapted to at least two frequency bands using cross-over filters and down sampling
c) the output from the band splitting algorithm is fed to at least two frequency band correction filter design algorithms
d) the output from the band correction filter design algorithms are fed to a delay and amplitude aligning algorithm
e) the output from the aligning algorithm is fed to a post processing algorithm
f) storing and using the output from the post processing algorithm to equalize in real time a sound source that is fed to the amplifier.

2. Method according to claim 1, characterized in that the output from the pre-processing algorithm is divided into typically three frequency bands, said tree bands are low-, mid- and high frequency bands respectively.

3. Method according to claim 1, wherein the output from the pre-processing algorithm is used as an input in a pre-correction algorithm, said pre-correction algorithm having at least one more input adapted to receive an output from one or more optional circuits representing certain acoustic impacts on a sound received in the listening position and said pre-correcting algorithm having an output that is fed to the frequency band correction filter design algorithm.

4. Method according to claim 3, characterized in that one of the optional circuits represents parameters measured from a loudspeaker under ideal conditions in an anechoic room.

5. Method according to claim 3, wherein one of the optional circuits represents parameters derived from psycho acoustic conditions.

6. Method according to claim 3, wherein the first 30 ms the reflections in the measured impulse response are attenuated more strongly than in the rest of the impulse response.

7. Method according to claim 1, wherein the aligning algorithm comprises aligning functionality for synchronizing the output from the band filters.

8. Method according to claim 1, wherein the aligning algorithm further comprises scaling and summation functionality.

9. Method according to claim 1, wherein the correction is performed in respect of certain part of a room in which the listener is placed.

10. Use of a method according to claim 1 in a multi channel set-up of speakers.
